(19) United States
(12) Patent Application Publication
(10) Pub. No.: US 2008/0011347 A1
(43) Pub. Date: Jan. 17, 2008

(54) CONNECTING LEAD WIRE FOR A SOLAR BATTERY MODULE, METHOD FOR FABRICATING SAME, AND SOLAR BATTERY MODULE USING THE CONNECTING LEAD WIRE

(75) Inventors: Seigi Aoyama, Kitaibaraki (JP); Takayuki Tsuji, Hitachi (JP); Hiroshi Okikawa, Hitachi (JP); Hajime Nishi, Hitachi (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 11/776,924

(22) Filed: Jul. 12, 2007

(30) Foreign Application Priority Data
Jul. 14, 2006 (JP) 2006-194708

(51) Int. Cl. H01L 31/05; H01L 31/02

(52) U.S. Cl. 136/244; 29/890.033

(57) ABSTRACT

A connecting lead wire is used for a solar battery module in which a plurality of solar battery cells connected in series by an inter-connector are arranged. The connecting lead wire is provided with a trunk portion and one or more branch portions. In the trunk portion, an enamel coating layer is provided on a conductor. In each of the branch portions, a solder plating layer is provided on a conductor. The branch portion protrudes from the trunk portion in a lateral direction, and connected to an electrode of each of the solar battery cells. The branch portion connects the solar battery cells with each other.

The present application is based on Japanese Patent Application No. 2006-194708 filed on Jul. 14, 2006, the entire contents of which are incorporated herein by reference.

### BACKGROUND OF THE INVENTION

1. Field of the Invention

The present invention relates to a connecting lead wire to be used in a solar battery module in which a plurality of solar battery cells are connected with a high density (a connecting lead wire for a solar battery), a method for fabricating the same, and a solar battery module using the connecting lead wire.

2. Related Art

As shown in FIG. 13, a conventional solar battery module 120 in many cases comprises a solar battery cell column including a plurality of solar battery cells c connected in series or in parallel by using an inter-connector 121 for lateral connection or a bus-bar for vertical connection. Japanese Patent No. 3437027 discloses such a conventional solar battery module.

As a connecting lead wire used in a conventional solar battery module, a connecting lead wire 131R to be installed on a right side of a module main body 120b and a connecting lead wire 131L to be installed on a left side of the module main body 120b are shown in an example of FIG. 13. For example, Japanese Patent Laid-Open No. 2003-86820 discloses a conventional solar battery module using this type of connecting lead wires.

The connecting lead wire 131R is used to electrically connect the module main body 120b with a cable for solar battery output (not shown), through which an electric current supplied from the module main body 120b is taken out. In addition, the connecting lead wire 131L is used to connect strings of the module main body 120b with each other. The string is a row of solar battery cells c that are connected in series by the inter-connectors 121).

As shown in FIG. 14, each of the connecting lead wires 131R, 131L comprises a trunk portion (bus bar) 132 and a plurality of branch portions 133, namely a first branch portion 133a and second branch portions 133b. The trunk portion 132 comprises a conductor 134, and an insulator 135 comprising an insulating film provided at necessary portion of an outer periphery of the conductor 134. The branch portion 133 may comprise the conductor 134. The branch portion 133 may also comprise the conductor 134 and the insulator 135 comprising an insulating film provided at necessary portion of an outer periphery of the conductor 134.

As described above, each of the lead wires 131R, 131L has an insulation configuration, in which the conductor 134 electrically connecting the inter-connector 121 at one string end portion with the inter-connector 121 at another string end portion is coated with an electrical insulator to provide the trunk portion 132.

According to this structure, a plurality of pieces of the lead wires 131R, 131L disposed adjacent to each other in the single solar battery module 120 are electrically insulated with each other, so that it is possible to prevent the electrical contact between the lead wire 131R and the lead wire 131L, thereby improving reliability of the solar battery module 120.

Next, a configuration of the connecting lead wire 131R will be explained.

As shown in FIG. 15, a semi-finished product 141 of the connecting lead wire 131R comprises the conductor 134 comprising a Cu-rod on which a fusion solder plating layer is formed, and the conductor 134 includes first and second branch portion pieces 143a, 143b (projecting pieces) that are connected at one end to each electrode of the solar battery cell c of FIG. 13, and a trunk portion piece 142 connected to another end of each of the first and second branch portion pieces 143a, 143b.

A connecting portion between the narrow first branch portion piece 143b and the trunk portion piece 142 (circle B in FIG. 15) and a connecting portion between the wide second branch portion piece 143a and the trunk portion piece 142 (circle A in FIG. 15) are connected by soldering the Cu-rod on which the solder plating layer is formed with using a heat plate.

As shown in FIG. 14, an insulator 135 comprising an insulating PET film with a thickness of around 0.05 mm (a thickness of an adhesive is around 0.03 mm) is stuck (laminated) on necessary points of an outer periphery of the trunk portion piece 142 of this semi-finished product 141 or the first branch portion piece 143a (or on both sides in case of using a rectangular conductor), to provide the connecting lead wire 131R.

Next, a method of fabricating the connecting lead wire 131R will be explained.

At first, a roll-shaped Cu-rod with a width of 3 to 5 mm is prepared, then the Cu-rod is slit (cut) with a desired width by means of a slit method which is generally used as a conventional cutting (slicing) method for a metallic material, to manufacture a plurality of strips each having a rectangular cross section (a metal cutting process). Solder plating is provided on an outer periphery of this strip (plating process). This solder plated rectangular wire is cut with a desired length, to manufacture a short length strip-shaped solder plated rectangular wire (a metal segmentation process). Trunk portion pieces and branch portion pieces are selected from a plurality of short length strip-shaped rectangular wires thus obtained, and respective connecting portions between the trunk portion piece and the branch portion piece are soldered, to provide the semi-finished product 141 having a configuration as shown in FIG. 15, for example (soldering process).

On the other hand, a roll-shaped PET film is prepared, and slit with a desired width, to provide a plurality of tape-shaped PET film (film cutting process). This tape-shaped PET film is cut to have a short length strip-shape with a desired length, to manufacture a plurality of short length strip-shaped films (film segmentation process). The semi-finished product 141 comprising the branch portion pieces and the trunk portion pieces is prepared, and the short length strip-shaped PET films are stuck on the semi-finished product 141 (film adhering process). Herein, three pieces of short length strip-shaped PET films are prepared. After positioning the PET films using a jig respectively, a part of the PET films are temporarily crimped, and finally stuck by crimping, to complete the connecting lead wire 131R.

As described above, the conventional solar battery module using this connecting lead wire is disclosed by Japanese Patent Laid-Open No. 2003-86820.

However, in the conventional connecting lead wire 131R, there are following disadvantages.

(i) When the insulating film is employed to cover the semi-finished product 141 similarly to the conventional device, the film cutting process, the film segmentation process, and the film adhering process are necessary. Particularly in the film adhering process, it is necessary to conduct a process of the temporary crimping and final crimping on a part of the insulating film one by one, so that the number of processes is increased and the process becomes complicated.

(ii) In the conventional device, it is necessary to stick a plurality of insulating films to each other, after manufacturing the semi-finished product 141 comprising the branch portion pieces and the trunk portion pieces, there by increasing the number of parts and components, so that a manufacturing cost is increased.

(iii) It is necessary to slit the roll-shaped Cu-rod with a desired width so as to manufacture the strips having a rectangular cross section. At the time of cutting the Cu-rod, burrs are produced. The burrs thus produced break through the insulating film and cause an electrical contact between the bus bars, so that a high reliability of the solar battery module 120 might not be expected.

(iv) So as to connect a plurality of solar battery cells c with a high density, it is necessary to install a number of the connecting lead wires for a solar battery module. However, when the lead wire 131R using the insulating film as shown in FIG. 14 is used, it is necessary to assure a width of the insulating film to some extent with respect to the trunk portion piece, so as to ensure the electrical insulation. Accordingly, a space for interconnection is increased and a freedom of layout is limited. Therefore, such a device is not suitable for the high density wiring.

### THE SUMMARY OF THE INVENTION

Accordingly, an object of the present invention is to provide a connecting lead wire for a solar battery module, a method for fabricating the same, and a solar battery module using the connecting lead wire, by which strings in the solar battery module are electrically connected with each other, an electrical insulation between the lead wires adjacently disposed is assured, and a production efficiency can be improved as well as a reduction in cost can be expected.

Further, another object of the present invention is to provide a connecting lead wire for a solar battery module, a method for fabricating the same, and a solar battery module using the connecting lead wire, by which a space for interconnection is assured enough, a freedom of layout can be improved, and a high density wiring can be expected.

According to a first feature of the invention, a connecting lead wire for a solar battery module, in which a plurality of solar battery cells connected in series by an inter-connector are arranged, the connecting lead wire comprises:

a trunk portion comprising a conductor and an enamel coating layer provided on the conductor; and

a plurality of branch portions, each of the branch portions comprising a conductor and a solder plating layer provided on the conductor and protruding from the trunk portion in a lateral direction to be connected to an electrode of each of the solar battery cells, to connect the solar battery cells with each other.

According to a second feature of the invention, in the connecting lead wire for a solar battery module, the trunk portion may further comprise a solder plating layer between the conductor and the enamel coating layer.

According to a third feature of the invention, a connecting lead wire for a solar battery module, in which a plurality of solar battery cells connected in series by an inter-connector are arranged, the connecting lead wire comprises:

a trunk portion comprising a conductor and an enamel coating layer provided on the conductor; and

a branch portion comprising a conductor and an enamel coating layer provided on the conductor and protruding from the trunk portion in a lateral direction, to take out an electric current from the solar battery cells.

According to a fourth feature of the invention, in the connecting lead wire for a solar battery module, the trunk portion may further comprise a solder plating layer between the conductor and the enamel coating layer, and the branch portion may further comprise a solder plating layer between the conductor and the enamel coating layer.

According to a fifth feature of the invention, in the connecting lead wire for a solar battery module, the trunk portion further comprises a conductor exposed part in which the enamel coating layer is removed.

According to a sixth feature of the invention, in the connecting lead wire for a solar battery module, the solder plating layer may comprise a Sn—Ag alloy, a Sn—Ag—Cu alloy, a Sn—Cu alloy, or a Sn—Pb alloy, which contains P of 0.002 to 0.02 mass %.

According to a seventh feature of the invention, in the connecting lead wire for a solar battery module, a lateral cross section of the conductor may be circular, elliptical, rectangular or polygonal.

According to an eighth feature of the invention, a method for fabricating a connecting lead wire for a solar battery module, in which a plurality of solar battery cells connected in series by an inter-connector are arranged, the method for fabricating the connecting lead wire comprises the steps of:

preparing a trunk portion comprising a conductor and an enamel coating layer provided on the conductor;

partially removing the enamel coating layer of the trunk portion to expose a part of the conductor; and

soldering a branch portion comprising a conductor and a solder plating layer provided on the conductor to the exposed part of the conductor of the trunk portion.

According to a ninth feature of the invention, in the method for fabricating a connecting lead wire for a solar battery module, the trunk portion may further comprise a solder plating layer between the conductor and the enamel coating layer.

According to a tenth feature of the invention, in the method for fabricating a connecting lead wire for a solar battery module, a part of the solder plating layer may be remained on the exposed part of the conductor of the trunk portion.

According to an eleventh feature of the invention, the method for fabricating a connecting lead wire for a solar battery module may further comprise the steps of partially removing an enamel coating layer provided on the solder plating layer of the branch portion to expose a part of the conductor, and soldering the exposed part of the conductor of the branch portion to the exposed part of the conductor of the trunk portion.

According to a twelfth feature of the invention, a method for fabricating a connecting lead wire for a solar battery module, in which a plurality of solar battery cells connected in series by an inter-connector are arranged, the method for fabricating the connecting lead wire comprises the steps of:

preparing a trunk portion comprising a conductor and an enamel coating layer provided on the conductor;

partially removing the enamel coating layer of the trunk portion to expose a part of the conductor; and

welding a branch portion comprising a conductor and a solder plating layer provided on the conductor to the exposed part of the conductor of the trunk portion.

According to a thirteenth feature of the invention, in the method for fabricating a connecting lead wire for a solar battery module, the trunk portion may further comprise a solder plating layer between the conductor and the enamel coating layer.

According to a fourteenth feature of the invention, in the method for fabricating a connecting lead wire for a solar battery module, a part of the solder plating layer may be remained on the exposed part of the conductor of the trunk portion.

According to a fifteenth feature of the invention, the method for fabricating a connecting lead wire for a solar battery module may further comprise the steps of partially removing an enamel coating layer provided on the solder plating layer of the branch portion to expose a part of the conductor, and welding the exposed part of the conductor of the branch portion to the exposed part of the conductor of the trunk portion.

According to a sixteenth feature of the invention, in the method for fabricating a connecting lead wire for a solar battery module, a resistance welding method is used for the welding.

According to a seventeenth feature of the invention, in the method for fabricating a connecting lead wire for a solar battery module, a method combining a resistance welding, a laser welding or an ultrasonic welding is used for the welding.

According to an eighteenth feature of the invention, in the method for fabricating a connecting lead wire for a solar battery module, the solder plating layer may comprise a Sn—Ag alloy, a Sn—Ag—Cu alloy, a Sn—Cu alloy, or a Sn—Pb alloy, which contains P of 0.002 to 0.02 mass %.

According to a nineteenth feature of the invention, a solar battery module comprises:

a plurality of solar battery cells connected in series by an inter-connector; and

a connecting lead wire for connecting the solar battery cells with each other, the connecting lead wire comprising:
a trunk portion comprising a conductor and an enamel coating layer provided on the conductor; and
a plurality of branch portions, each of the branch portions comprising a conductor and a solder plating layer provided on the conductor and protruding from the trunk portion in a lateral direction to be connected to an electrode of each of the solar battery cells.

According to the present invention, since an enamel wire is used as parts of the lead wire, it is not necessary to use the insulating film. Further, the manufacturing process can be reduced, as well as the electrical insulation between the adjacent lead wires can be surely expected.

### BRIEF DESCRIPTION OF THE DRAWINGS

Next, the present invention will be explained in more detail in conjunction with appended drawings, wherein:

FIGS. 1A to 1C are diagrams showing a connecting lead wire for a solar battery module in a first preferred embodiment according to the invention, wherein FIG. 1A is a plan view of the connecting lead wire for a solar battery module, FIG. 1B is a lateral cross sectional view of a trunk portion or a branch portion of with a first enamel configuration, and FIG. 1C is a lateral cross sectional view of a trunk portion or a branch portion with a second enamel configuration;

FIG. 2 is a perspective view of a connecting lead wire for a solar battery module (connection by soldering) in a second preferred embodiment according to the invention;

FIG. 3 is a perspective view of a connecting lead wire for a solar battery module (connection by soldering) in a third preferred embodiment of the invention;

FIG. 4 is a perspective view of a connecting lead wire for a solar battery module (connection by soldering) in a fourth preferred embodiment according to the invention;

FIG. 5 is a perspective view of a connecting lead wire for a solar battery module (connection by soldering) in a fifth preferred embodiment according to the invention;

FIG. 6 is a perspective view of a connecting lead wire for a solar battery module (connection by soldering) in a sixth preferred embodiment according to the invention;

FIG. 7 is a perspective view of a connecting lead wire for a solar battery module (bonding by ultrasonic welding) in a seventh preferred embodiment according to the invention;

FIG. 8 is a perspective view of a connecting lead wire for a solar battery module (bonding by ultrasonic welding) in an eighth preferred embodiment according to the invention;

FIG. 9 is a perspective view of a connecting lead wire for a solar battery module (connection by soldering of a rectangular wire) in a ninth preferred embodiment according to the invention;

FIG. 10 is a perspective view of a connecting lead wire for a solar battery module (bonding by ultrasonic welding of a rectangular wire) in a tenth preferred embodiment according to the invention;

FIG. 11 is a perspective view of a connecting lead wire for a solar battery module (connection by soldering of a rectangular wire) in an eleventh preferred embodiment according to the invention;

FIG. 12 is a plan view of a solar battery part which is a main part of a solar battery module in the preferred embodiments according to the invention;

FIG. 13 is a plan view of a solar battery part which is a main part of a conventional solar battery module;

FIG. 14 is a plan view of a connecting lead wire for a conventional solar battery module; and

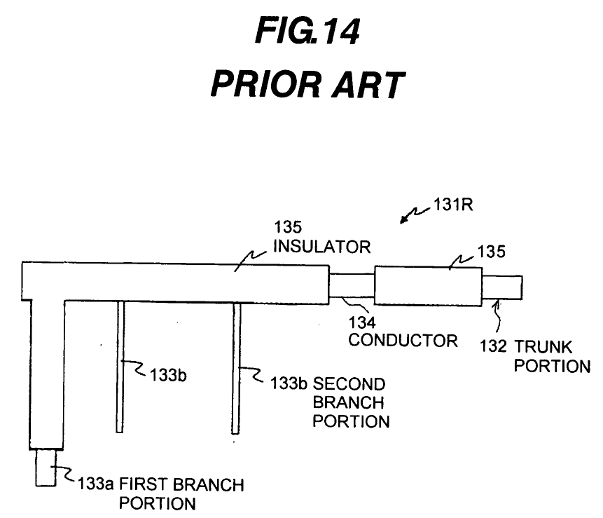

FIG. 15 is a plan view of a semi-finished product of a connecting lead wire shown in FIG. 14 (before providing an insulation film coating).

### DESCRIPTION OF THE PREFERRED EMBODIMENTS

Next, preferred embodiments according to the present invention will be explained in more detail in conjunction with the appended drawings.

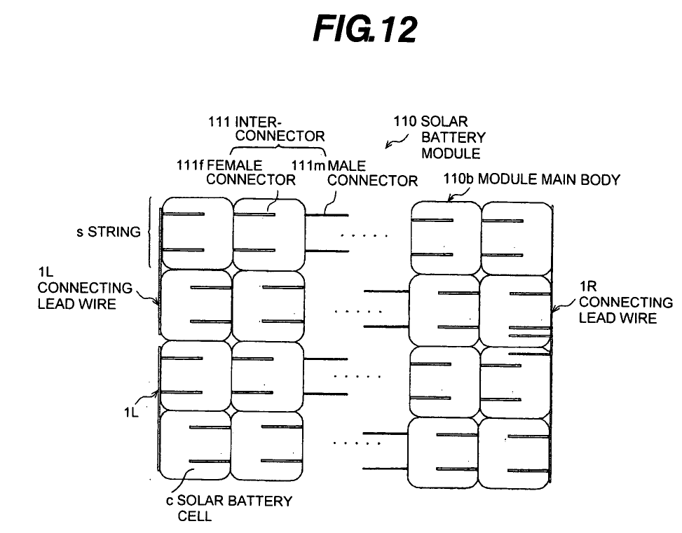

Firstly, a solar battery module using a connecting lead wire for a solar battery module in the preferred embodiment will be explained with referring to FIG. 12.

As shown in FIG. 12, a solar battery module 110 in the preferred embodiment mainly comprises a module main body 110b, and connecting lead wires 1R, 1L for a solar battery module in the first preferred embodiment, in which the connecting lead wires 1R, 1L are connected to the module main body 110b.

The module main body 110b comprises a plurality of solar battery cells c, each of which generates an electric current from irradiation of a light such as sunlight, illuminating light. At one side of each the solar battery cell c, a male connector 111m which functions as an electrode for connecting the solar battery cells c to each other in series is provided, and at another side, a female connector 111f which functions as an electrode for engaging with the male connector 111m is provided. The male connector 111m and the female connector 111f constitute an inter-connector 111 for connecting a plurality of the solar battery cells c in a lateral direction.

FIG. 12 shows an example of the module main body 110b, in which the solar battery cells c are connected in series by the inter-connectors 111 to constitute a string (a group of cells) s, and a plurality of the strings s are vertically arranged in four columns.

The connecting lead wire 1L in this preferred embodiment is connected to one end of the module main body 110b. The connecting lead wire 1L is used to connect vertically a string s at a first stage with respect to an upper side of the module main body 110b to a string s at a second stage, and a string s at a third stage to a string s at a fourth stage, respectively, so as to connect two solar battery cells c at a left end of each string s.

The connecting lead wire 1R in this preferred embodiment is connected to another end of the module main body 110b. The connecting lead wire 1R is used to electrically connect between the module main body 110b and a cable for a solar battery output (not shown) to take out the electric current from the module main body 110b.

In other words, the connecting lead wire 1R is a lead wire for connecting between the module main body 110b and the cable for solar battery output, so as to take out the electric current from all the solar battery cells c to the outside.

FIG. 12 shows the example in which two connecting lead wires 1L are connected to the one end of the module main body 110b, and two connecting lead wires 1R are connected to a front side and a back side of another end of the module main body 110b. One of the two connecting lead wires 1R is provided as a plus (+) side lead wire and another one is provided as a minus (−) side lead wire, so as to take out the electric current to the outside from all the solar battery cells c that are connected in series.

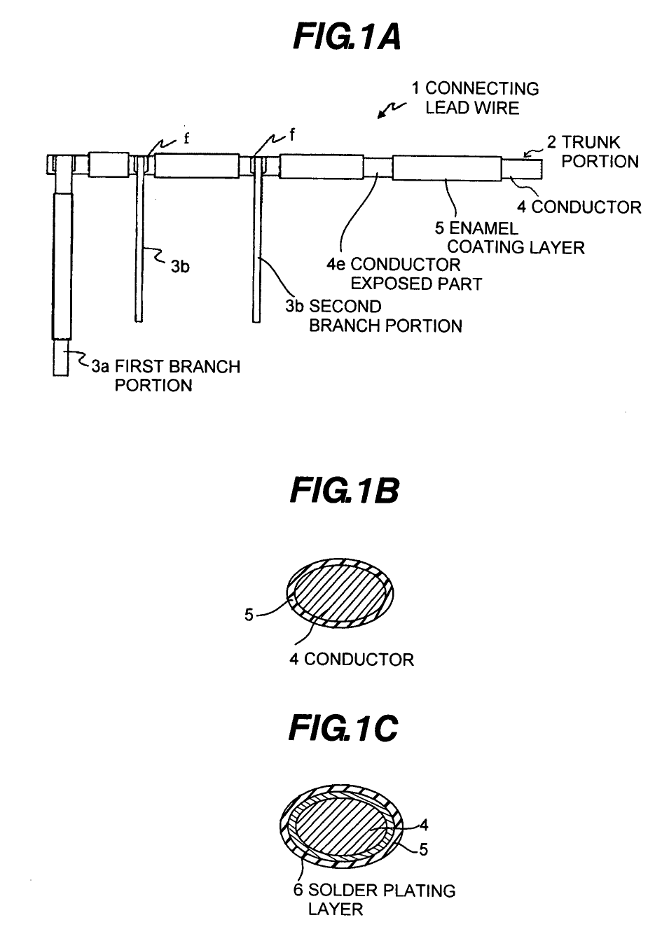

Herein, the connecting lead wire in the first preferred embodiment according to the present invention will be explained in more detail with referring to FIGS. 1A to 1C.

FIGS. 1A to 1C are diagrams showing a connecting lead wire for a solar battery module in the first preferred embodiment according to the invention, wherein FIG. 1A is a plan view of the connecting lead wire for a solar battery module, FIG. 1B is a lateral cross sectional view of a trunk portion or a branch portion with a first enamel configuration, and FIG. 1C is a lateral cross sectional view of a trunk portion or a branch portion with a second enamel configuration.

As shown in FIG. 1A, a connecting lead wire 1 in the first preferred embodiment is an enamel wire comprising a linear trunk portion 2, and a plurality of branch portions. The branch portion includes a first branch portion 3a with a large diameter which extends in a lateral direction from the trunk portion 2 (in other words, protrudes from one side of the trunk portion 2), and second branch portions 3b with a small diameter. In this example shown in FIG. 1A, the number of the first branch portion 3a is one, the number of the second branch portion 3b is two, and a total number of the branch portions is three. For example, this connecting lead wire 1 may be used as connecting lead wire 1R of FIG. 12.

Enamel wire configuration of the trunk portion 2 may be classified in two types A and B. The trunk portion 2 according to a first enamel wire configuration A has no solder plating layer. The trunk portion 2 according to a second enamel wire configuration B has a solder plating layer.

FIG. 1B shows the first enamel wire configuration A, in which an enamel coating layer 5 is provided on a conductor (center conductor) 4. As for the conductor 4, a Cu-wire (For example, a tough pitch Cu-wire, an oxygen free Cu-wire) is preferable. A lateral cross section of the conductor 4 is not limited, and may be circular, elliptical, rectangular or polygonal. As for the enamel coating layer 5, for example, a polyurethane enamel coating, a polyesterimide enamel coating, a polyamideimide enamel coating, a brazing enamel coating or the like may be used.

FIG. 1C shows the second enamel wire configuration B, in which a solder plating layer 6 is provided on the conductor 4, and the enamel wire coating layer 5 is provided on the solder plating layer 6. As for the conductor 4, a Cu-wire or a Cu-rod (For example, a tough pitch Cu-wire, an oxygen free Cu-wire, a Cu-alloy wire mainly composed of Cu, and an Ag alloy wire mainly composed of Ag) is preferable.

The trunk portion 2 is provided with the enamel coating layer 5 at its outer periphery portion, except at least both ends and a bonding part with the second branch portion 3b with a small diameter (a conductor exposed part 4e in which the enamel coating layer 5 is removed to expose a surface of the conductor 4 or the solder plating layer 6).

As for a material of the solder plating layer 6, it is preferable to use such material that the solder plating layer is hard to melt by heat when annealing at a high temperature after applying an enamel coating material on the solder plating layer. It is preferable to use an electroplating high melting point solder layer containing Sn of not less than 90%, or a high melting point solder plating layer composed of a fusion solder, an electroless plating solder, or the like.

In addition, as for the solder plating layer 6, it is preferable to use a Sn—Ag alloy, a Sn—Ag—Cu alloy, a Sn—Cu alloy, or a Sn—Pb alloy, which contains P of 0.002 to 0.02 mass % (wt %).

When an alloy composition of the solder contains P of 0.002 to 0.02 mass %, it is possible to form a solder plating layer which is hard to generate an oxide film. The reason for limiting a content of P is as follows. When the content of P is less than 0.002 mass %, and an effect for suppressing the oxide film formation is not sufficiently obtained. When the content of P exceeds 0.02 mass %, the effect obtained by adding P tends to be saturated.

The first branch portion 3a with a large diameter has the same diameter as that of the trunk portion 2. Similarly to the trunk portion 2, enamel wire configuration of the first branch portion 3a may be classified in two types A and B. The first branch portion 3a with a large diameter has the conductor exposed parts 4e at both ends, and the conductor exposed part 4e at one end of the first branch portion 3a with a large diameter is connected to one end of the trunk portion 2. The conductor exposed part 4e at another end of the first branch portion 3a with a large diameter is connected to an electrode formed in the solar battery cell c of FIG. 12.

The second branch portion 3b with a small diameter comprises a conductor 4, and may further comprise a solder plating layer 6 provided at an outer periphery of the conductor 4. At one end, the second branch portion 3b with a small diameter is connected to the conductor exposed part 4e except the both ends of the trunk portion 2, and at another end, the second branch portion 3b with a small diameter is connected to the female connector 111f formed at the solar battery cell c of FIG. 12. An interval between the two second branch portions 3b, 3b is the same as an interval between the male connector 111m and the female connector 111f.

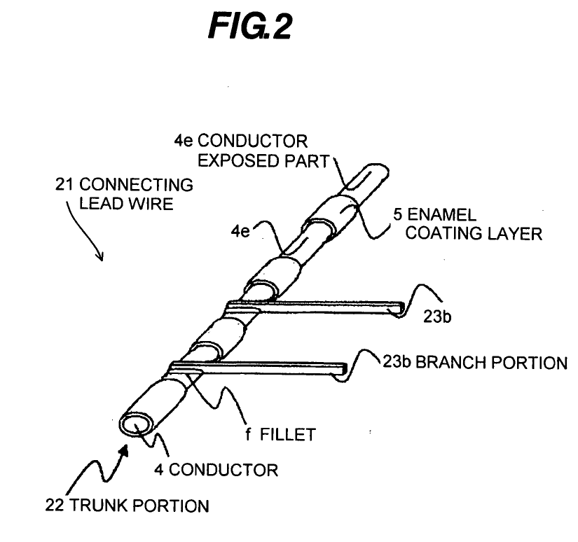

In the example of FIG. 1A, the connecting lead wire 1 having the configuration as described above is formed to be approximately pectinate (dented shape) in a plan view. In examples of FIG. 2 to be described below, the connecting lead wire 1 is formed to have a reverse-F or a reverse-Γ in a plan view.

Next, a method for fabricating a connecting lead wire 1 will be explained below.

Firstly, a conductor wire or a conductor rod is prepared, and an enamel coating material is applied and annealed repeatedly to provide an enamel coating layer 5, so that an enamel wire is obtained. In this enamel wire, a part of the enamel coating layer 5 is removed at plural desired positions respectively for the trunk portion 2 and the first branch portion 3a. For removing the enamel coating layer 5, it is possible to use a mechanical method of polishing the enamel coating layer 5 by abrasives and a chemical method of etching the enamel coating layer 5 by an etchant with using a mask.

The enamel wire, from which the enamel coating layer 5 is removed at predetermined point, is cut with a predetermined length in accordance with the trunk portion 2 or the first branch portion 3a, to provide a segmented enamel wire.

On the other hand, a conductor wire or a conductor rod is separately prepared. Alternatively, a solder plated conductor wire or a solder plated conductor rod, in which a solder plating layer is provided at its outer periphery, may be separately prepared. The separately prepared conductor wire or conductor rod is cut with a predetermined length in accordance with the second branch portion 3b, to provide a segmented conductor wire or a conductor rod (metal segmentation process).

The first and second branch portions 3a, 3b are bonded to the respective conductor exposed parts 4e of the trunk portion 2 by soldering or welding, to provide the connecting lead wire 1 of FIG. 1A (soldering process or welding process).

1) Soldering Process

A coating removed part (conductor exposed part 4e) of the segmented enamel wire to be used as the first branch portion 3a and one end of the segmented conductor wire or the segmented conductor rod to be used as the second branch portion 3b are connected by soldering to a coating removed part (conductor exposed part 4e) of the segmented enamel wire to be used as the trunk portion 2. At a periphery of a bonding part, a fillet f comprising a solder plating is formed, so that an excellent bonding condition is obtained.

2) Welding Process

As for the welding method, there are a method using only a resistance welding and a method combining a resistance welding, a laser welding, an ultrasonic welding, or the like. The resistance welding and the laser welding can be conducted by the conventional methods. Therefore, the method using the ultrasonic welding will be explained below.

At first, the segmented enamel wire to be used as the first branch portion 3a is superimposed on the conductor exposed part 4e of the segmented enamel wire to be used as the trunk portion 2.

While pressurizing the superimposed part between a pair of sonotrode chips of an ultrasonic welding apparatus, a supersonic wave is provided between a pair of the sonotrode chips. By this ultorasonic welding, a crushing work is conducted on a welding end between the conductor wire or the conductor rod and the enamel wire, by pressurizing in the ultrasonic welding, a surface of the first branch portion 3a and a surface of the trunk portion 2 are approximately in the same surface. Therefore, when the ultrasonic welding is used, a thickness of the whole connecting lead wire 1 can be reduced to half, compared with the case where the other welding method is used.

In addition, the welding of the conductor exposed part 4e of the segmented enamel wire to be used with the trunk portion 2 and the segmented solder plating conductor wire or conductor rod to be used as the second branch portion 3b can be conducted by the ultrasonic welding in a similar manner to the above. Since the solder plating layer is provided in the solder plating conductor wire or conductor rod side in this case, a good bonding condition can be obtained, even when the solder plating layer is not provided in the enamel wire side to be used as the trunk portion 2.

By the method same as that of the connecting lead wire 1 as described above, the connecting lead wires 1R, 1L may be fabricated in accordance with the module main body 110b of FIG. 12 for example, and the connecting lead wires 1R, 1L thus fabricated may be connected to the module main body 110b, so as to provide the solar battery module 110.

Next, an effect of the first preferred embodiment will be explained below.

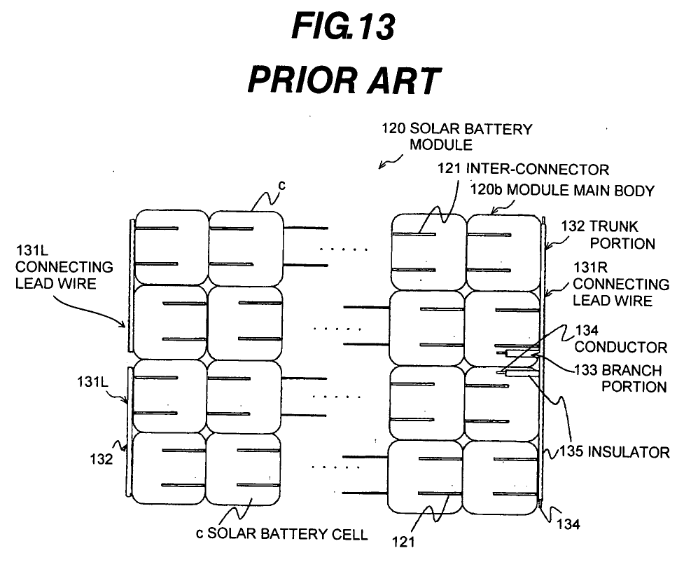

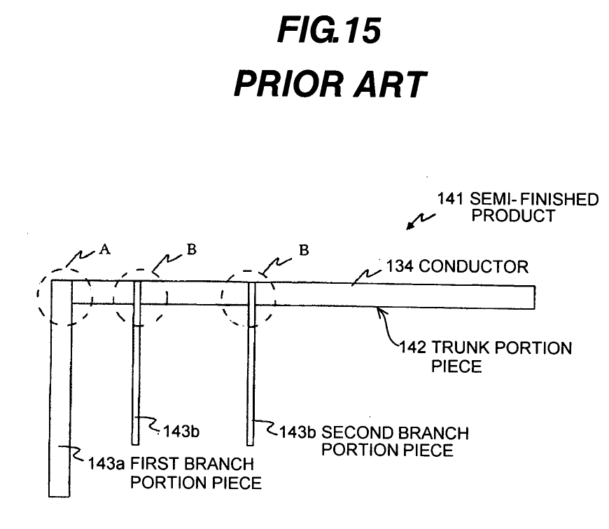

In the conventional connecting lead wires 131R, 131L explained in FIG. 13, the insulating film is laminated on the conductor to provide the electrical insulation. However, since the insulating film is used, the manufacturing process is increased and the process is complicated. In addition, since it is necessary to partially apply the insulating film of a plurality of pieces to each other after fabricating the semi-finished product 141 of FIG. 15 comprising the branch portions and the trunk portion, the number of components is increased to provide the electrical insulation, and the cost is increased.

Therefore, according to the connecting lead wire 1 in this preferred embodiment, it is not necessary to use the conventional insulating film since the enamel wire is used as a component. Further, it is possible to electrically connect the strings s in the solar battery module 110 to each other, and to assure the electrical insulation between the lead wires adjacently disposed (for example, the two connecting lead wires 1R to be connected with each other and two connecting lead wires 1L to be connected with each other of FIG. 12).

In particular, the enamel coating layer 5 has a layer thickness (film thickness) of a few hundredth of a millimeter that is significantly thinner and a superior electrical insulation compared with the conventional insulating film. Therefore, by using the connecting lead wire 1, a space for interconnection can be provided enough in the solar battery module 110, a freedom of layout can be provide and the high density wiring can be realized. Accordingly, miniaturization and reduction in weight of the connecting lead wire 1 per se and the solar battery module 110 can be expected.

Further, as described in connection with the method of fabrication, the formation of the enamel coating layer 5 is simple, and a partial removal of the enamel coating layer 5 is easy. Therefore, compared with the conventional connecting lead wires 131R, 131L, the manufacturing process can be reduced, the production efficiency can be improved, and the reduction in cost can be expected.

Further, in the connecting lead wire 1 in this preferred embodiment, it is possible to coat only the conductor 4 at required points of the trunk portion 2 and the first and second branch portions 3a, 3b with the enamel coating layer 5 to provide the electrical insulation. Accordingly, the conductor exposed part 4e can be formed at a desired position in accordance with a shape and a type of the module main body 110b, so that freedom of configuration of the lead wire per se is increased. Since the conductor exposed part 4e is formed at the bonding part between the trunk portion 2 and the branch portions 3a, 3b in the connecting lead wire 1, the strength of the bonding part can be maintained enough even when the enamel wire is used.

Next, other preferred embodiments according to the present invention will be explained with referring to FIGS. 2 to 11.

FIG. 2 shows a connecting lead wire 21 comprising a trunk portion 22 and two branch portions 23b bonded to the trunk portion 22 by soldering, to have a substantially reverse-F shape. The trunk portion 22 comprises a conductor 4 having a substantially circular lateral cross section, an enamel coating layer 5 on the conductor 4, and conductor exposed parts 4e at four points. Each of the branch portions 23b comprises a solder plated rectangular wire. For example, this connecting lead wire 21 is used as the connecting lead wire 1L of FIG. 12.

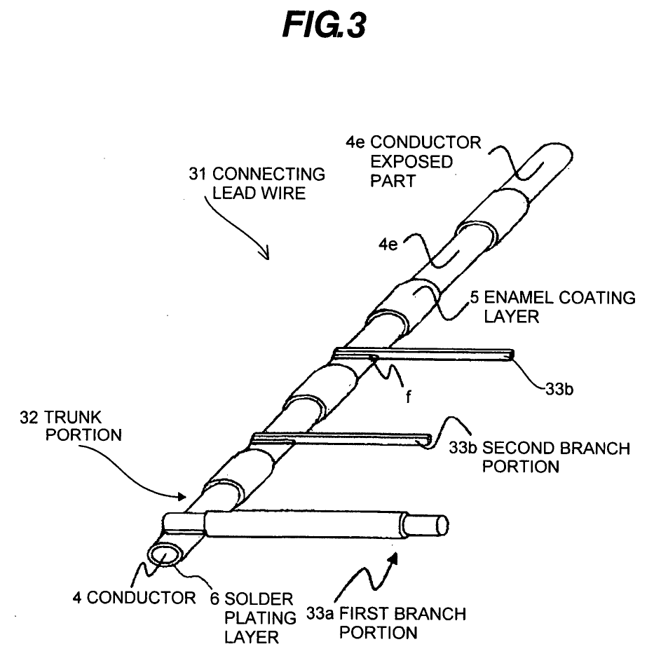

FIG. 3 shows a connecting lead wire 31 comprising a trunk portion 32, a first branch portion 33a bonded to one end of the trunk portion 32 by soldering, and two second branch portions 33b bonded to the trunk portion 32 at a side of the first branch portion 33a by soldering to be approximately pectinate. The trunk portion 32 comprises a conductor 4 having a substantially circular lateral cross section, a solder plating layer 6 provided on the conductor 4, and an enamel coating layer 5 provided on the solder plating layer 6, and conductor exposed parts 4e at five points. The first branch portion 33a is made of the same material as that of the trunk portion 32. Each of the second branch portions 33b comprises a solder plated rectangular wire.

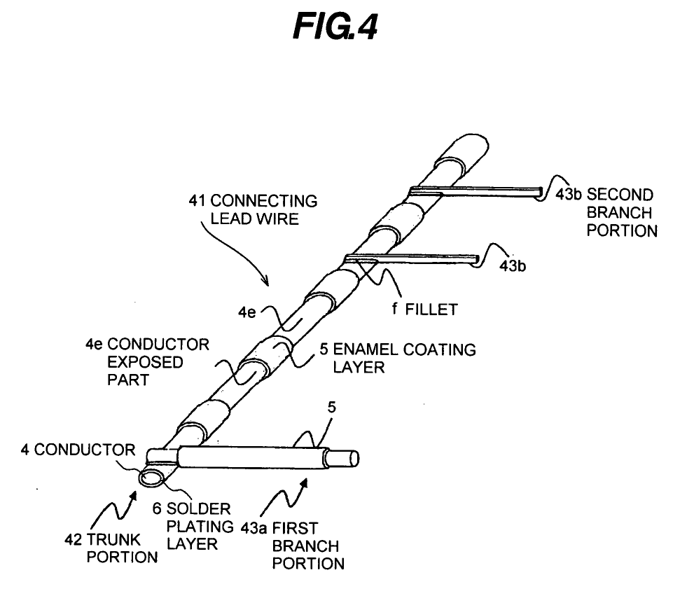

FIG. 4 shows a connecting lead wire 41 comprising a trunk portion 42, a first branch portion 43a bonded to one end of the trunk portion 42 by soldering, and two second branch portions 43b bonded to another end of the trunk portion 42 at a side distant from the first branch portion 43a by soldering to be approximately pectinate. The trunk portion 42 comprises a conductor 4 having a substantially circular lateral cross section, a solder plating layer 6 provided on the conductor 4, and an enamel coating layer 5 provided on the solder plating layer 6, and conductor exposed parts 4e at five points. The first branch portion 43a is made of the same material as that of the trunk portion 42. Each of the second branch portions 43b comprises a solder plated rectangular wire.

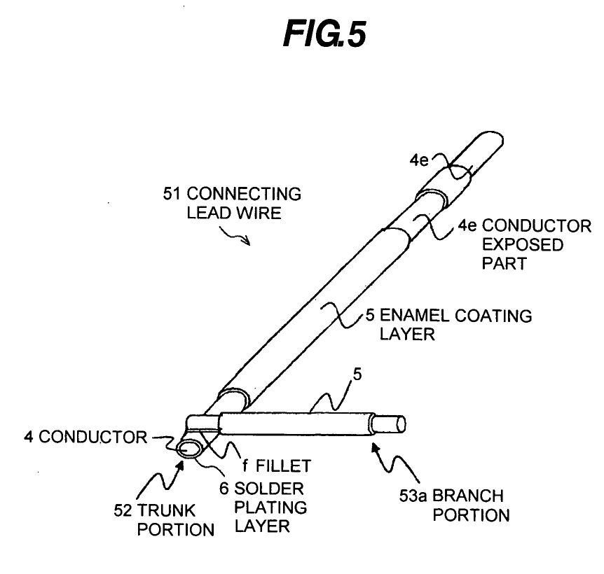

FIG. 5 shows a connecting lead wire 51 comprising a trunk portion 52, and a branch portion 53a bonded to one end of the trunk portion 52 by soldering to have a substantially reverse-Γ. The trunk portion 52 comprises a conductor 4 having a substantially circular lateral cross section, a solder plating layer 6 provided on the conductor 4, and an enamel coating layer 5 provided on the solder plating layer 6, and conductor exposed parts 4e at three points. The branch portion 53a is made of the same material as that of the trunk portion 52.

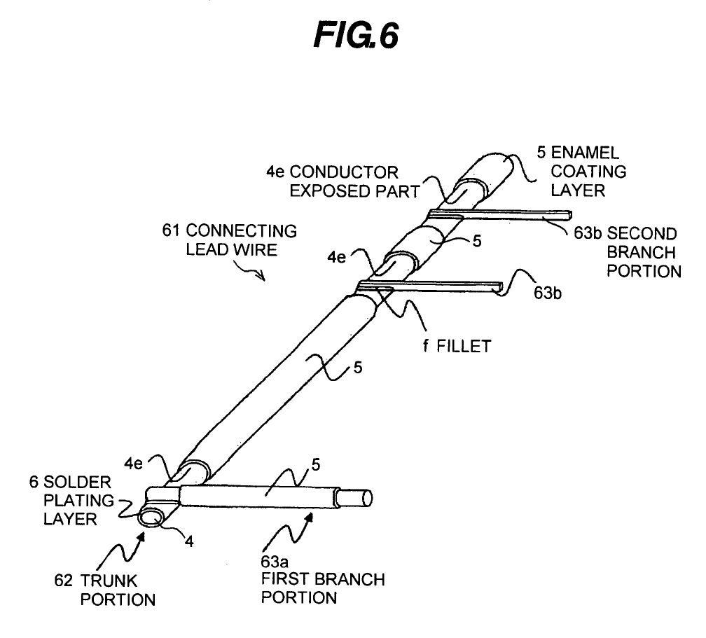

FIG. 6 shows a connecting lead wire 61 comprising a trunk portion 62, a first branch portion 63a bonded to one end of the trunk portion 62 by soldering, and two second branch portions 63b bonded to another end of the trunk portion 62 at a side distant from the first branch portion 63a by soldering to be approximately pectinate. The trunk portion 62 comprises a conductor 4 having a substantially circular lateral cross section, a solder plating layer 6 provided on the conductor 4, and an enamel coating layer 5 on the solder plating layer 6, and conductor exposed parts 4e at three points. The first branch portion 63a is made of the same material as that of the trunk portion 62. Each of the second branch portions 63b comprises a solder plated rectangular wire.

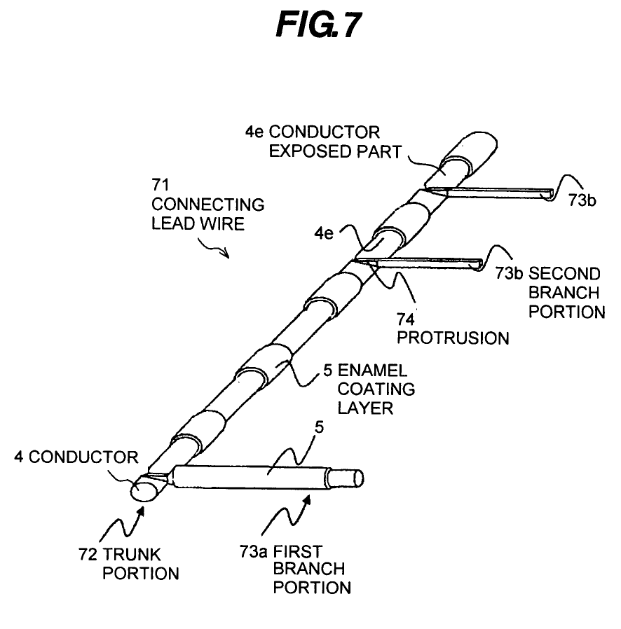

FIG. 7 shows a connecting lead wire 71, in which bonding between the trunk portion and the branch portions is conducted by the ultrasonic welding for the connecting lead wire 41 in FIG. 4. In FIG. 7, a connecting lead wire 71 comprises a trunk portion 72, a branch portion 73a bonded to one end of the trunk portion 72 by the ultrasonic welding, and two branch portions 73b bonded to another end of the trunk portion 12 at a side distant from the branch portion 73a by the ultrasonic welding to be approximately pectinate. The trunk portion 72 comprises a conductor 4 having a substantially circular lateral cross section, and an enamel coating layer 5 provided on the conductor 4, and conductor exposed parts 4e at five points. The branch portion 73a is made of the same material as that of the ink portion 12. Each of the branch portions 73b comprises a solder plated rectangular wire.

In each of the branch portions 73a, 73b, a protrusion 74 is provided to protrude in a longitudinal direction at a part bonded to the conductor exposed part 4e of the trunk portion 72, and a part of the protrusion 74 is formed to have a shape along an outer periphery of the conductor exposed part 4e.

The ultrasonic welding is a kind of diffusion bonding methods, and is different from the resistance welding and the laser welding, as the metal does not melt in the bonding part according to the ultrasonic welding. Therefore, a bonding area with the trunk portion 72 is increased by providing the protrusion 74 in each of the branch portions 73a, 73b, so that the strength of the bonding part is improved.

In addition, since the connecting lead wire 71 is fabricated by the ultrasonic welding, it is not necessary to provide the solder plating layer in the trunk portion 72 and the branch portions 73a, 73b.

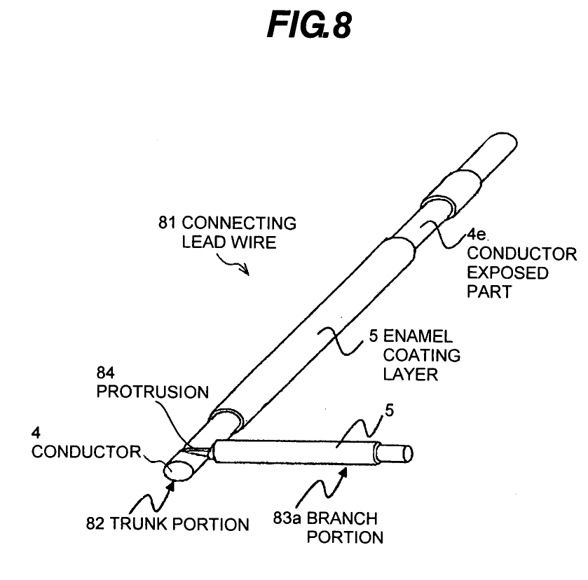

FIG. 8 shows a connecting lead wire 81, in which bonding between the trunk portion and the branch portions is conducted by the ultrasonic welding for the connecting lead wire 51 in FIG. 5. In FIG. 8, a connecting lead wire 81 comprises a trunk portion 82, and a branch portion 83a bonded to one end of the trunk portion 82 by the ultrasonic welding to have a substantially reverser-Γ. The trunk portion 82 comprises a conductor 4 having a substantially circular lateral cross section, and an enamel coating layer 5 provided on the conductor 4, and conductor exposed parts 4e at three points. The branch portion 83a is made of the same material as that of the trunk portion 82. In this branch portion 83a, a protrusion 84 similar to the protrusion 74 of FIG. 7 is provided.

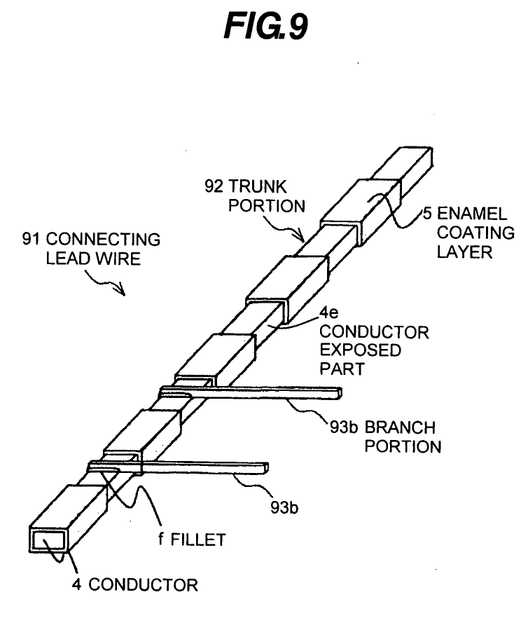

FIG. 9 shows a connecting lead wire 91 which is a variation of the connecting lead wire 21 of FIG. 2. A connecting lead wire 91 comprises a trunk portion 92 and two branch portions 93b bonded to the trunk portion 92 by soldering, to have a substantially reverse-F shape. The trunk portion 92 comprises a rectangular wire composed of a conductor 4 having a rectangular lateral cross section and an enamel coating layer 5 on the conductor 4, and conductor exposed parts 4e at four points. Each of the branch portions 93b comprises a solder plated rectangular wire.

In this connecting lead wire 91, since the solder plated wire having a rectangular lateral cross section comprises a solder plating layer, it is not necessary to specially provide a solder plating layer at an enamel wire side for the solder bonding with the enamel wire to be used for the trunk portion 92.

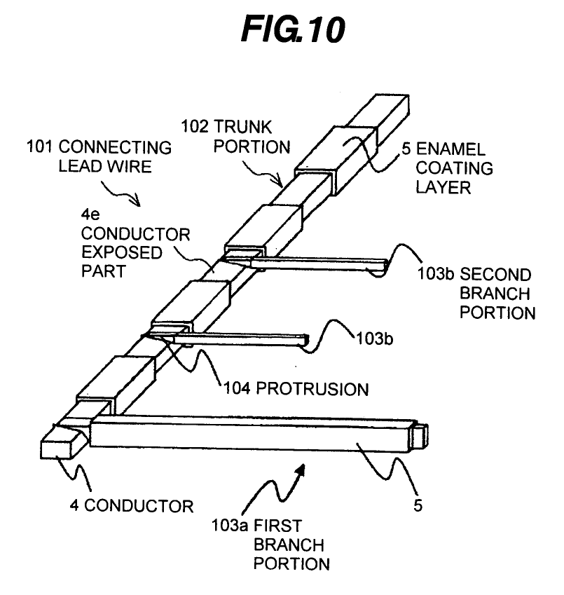

FIG. 10 shows a connecting lead wire 101 which is a variation of the connecting lead wire 31 of FIG. 3. A connecting lead wire 101 comprises a trunk portion 102, a first branch portion 103a bonded to one end of the trunk portion 102 by the ultrasonic welding, and two second branch portions 103b bonded to the trunk portion 102 at a side of the first branch portion 103a by the ultrasonic welding to be approximately pectinate. The trunk portion 102 comprises a rectangular wire composed of a conductor 4 having a rectangular lateral cross section and an enamel coating layer 5 on the conductor 4, and conductor exposed parts 4e at five points. The first branch portion 103a comprises a rectangular wire that is the same material as that of the trunk portion 102. Each of the second branch portions 103b comprises a solder plated rectangular wire.

In these branch portions 103a, 103b, a protrusion 104 similar to the protrusion 74 of FIG. 7 is provided respectively.

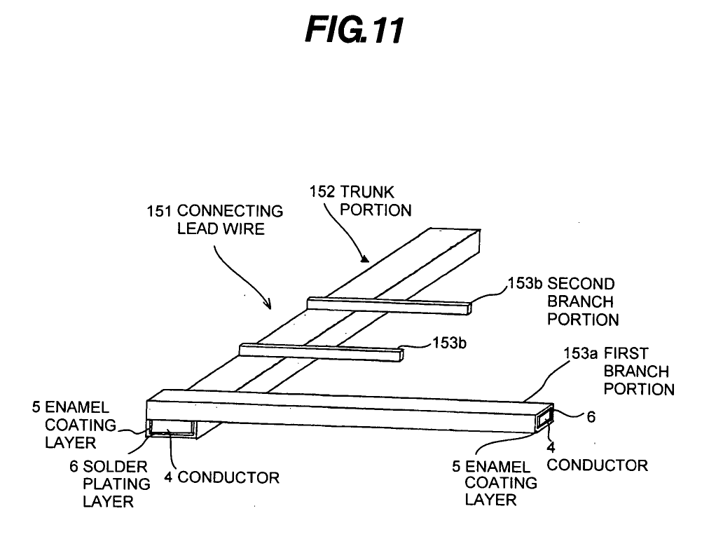

FIG. 11 shows a connecting lead wire 151 comprising a trunk portion 152, a first branch portion 153a bonded to one end of the trunk portion 152 by soldering, and two second branch portions 153b bonded to the trunk portion 152 at a side of the first branch portion 153a by soldering to be approximately pectinate. The trunk portion 152 comprises a rectangular wire composed of a conductor 4 having a rectangular lateral cross section, a solder plating layer 6 provided on the conductor 4, and an enamel coating layer 5 on the solder plating layer 6. The first branch portion 153a comprises a rectangular wire that is the same material as that of the trunk portion 152. Each of the second branch portions 153b comprises a solder plated rectangular wire. In this preferred embodiment, no conductor exposed part is provided, since the trunk portion 152 and the branch portion 153 comprise the enamel coating layer 5 and the direct soldering can be conducted.

According to the respective connecting lead wires 21 to 151 of FIGS. 2 to 11, the same function and effect as those of the connecting lead wire 1 of FIG. 1 can be obtained.

In the connecting lead wire according to the present invention as described above, the trunk portion may have the enamel wire configurations A or B, the first branch portion with a large diameter may have the enamel wire configuration A or B, and the second branch portion with a small diameter may comprise a conductor per se or a plated wire. Therefore, there are eight kinds of combinations in total.

### EXAMPLE

### Example 1

### Corresponding to the Connecting Lead Wire 21 of FIG. 2

At first, a Cu-wire (center conductor) 4 having a conductor diameter of φ1.5 mm is prepared. Then, a brazing polyurethane enamel coating material is applied to the Cu-wire 4 and annealed repeatedly until a thickness of the brazing polyurethane enamel coating becomes 0.04 mm, so as to provide an enamel wire. An enamel coating layer 5 is removed in plural points at desired positions by mechanical method, and the enamel wire is cut with a length of 0.4 mm, to provide a segmented enamel wire (metal segmentation process).

On the other hand, two solder plated wires each having a rectangular cross section are prepared (branch portion 23b). The solder plated wire is fabricated by providing a solder plating layer (Sn—Pb fusion solder plating containing P of 0.01 mass %) on a Cu-wire.

As described above, the enamel coating layer 5 of the enamel wire to be used as a trunk portion 22 is removed at desired positions of a center part and both ends to expose the conductor 4 at two points (conductor exposed parts 4e). Then, the solder plated wires each having a rectangular cross section (branch portions 23b) are soldered to the conductor exposed parts 4e (soldering process), to provide the connecting lead wire 21 of FIG. 2.

Thereafter, the branch portions 23b are connected by soldering to electrodes at solar battery cells c at one side. The trunk portion 22 has the conductor exposed parts 4e in which the enamel coating layer 5 is removed, at an end opposite to another end where the branch portions 23b are provided and at a region adjacent to the center part with respect to another end. In other words, the branch portions 23b are not provided at the conductor exposed parts 4e at another end and the region adjacent to another end as shown in FIG. 2. These conductor exposed parts 4e are soldered to connecting portions installed in solar battery cells c at another side, so that the connecting lead wire 21 is installed in a module main body 110b, so as to fabricate a solar battery module 110.

It is not necessary to specially form a solder plating layer at an enamel wire side in the solder bonding with the enamel wire to be used as the trunk portion 22, since the solder plated wire having a rectangular cross section comprises a solder plating layer. In other words, the solder plating layer is provided in the solder plated rectangular wire prior to the solder bonding.

### Example 2

### Corresponding to the Connecting Lead Wire 31 of FIG. 3, the Connecting Lead Wire 41 of FIG. 4, and the Connecting Lead Wire 61 of FIG. 6

At first, a Cu-wire (center conductor) 4 having a conductor diameter of φ1.5 mm is prepared. Then, a high melting point solder comprising Sn-3 wt %/Ag-0.5 wt % Cu and inevitable impurities is provided on the Cu-wire 4 by electrolysis electroplating method until a thickness of a solder plating layer 6 became 0.02 mm. Thereafter, a brazing polyurethane enamel coating material is applied to the high melting point solder plated Cu-wire 4 and annealed repeatedly, so as to provide an enamel wire. An enamel coating layer 5 is removed in plural points at desired positions by mechanical method, and the enamel wire is cut with a length of 0.4 m, to provide a segmented enamel wire (metal segmentation process).

On the other hand, two solder plated wires each having a rectangular cross section are prepared (second branch portions 33b, 43b, or 63b). The solder plated wire is fabricated by providing a solder plating layer 6 (Sn—Pb fusion solder plating containing P of 0.01 mass %) on a Cu-wire 4.

One enamel wire to be used as a trunk portion 32, 42, or 62 in which the enamel coating layer 5 is removed at desired positions to expose the conductor 4 at predetermined points (conductor exposed parts 4e) is selected. Another enamel wire (first branch portion 33a, 43a, or 63a) having the conductor exposed at both ends is soldered to the conductor exposed part 4e at one end of the enamel wire to be used as the trunk portion 32, 42, or 62. Solder plated wires each having a rectangular cross section (second branch portions 33b, 43b or 63b) are soldered to other conductor exposed parts 4e of the enamel wire to be used as the trunk portion 32, 42, or 62 at two points (the conductor exposed parts 4e adjacent to the enamel wire functioning as the first branch portion 33a in FIG. 3, the conductor exposed parts 4e distant from the enamel wire functioning as the first branch portion 43a or 63a in FIG. 4 or 6) (soldering process), to provide the connecting lead wire 31 of FIG. 3, the connecting lead wire 41 of FIG. 4, or the connecting lead wire 61 of FIG. 6.

The second branch portions 33b, 43b, or 63b are connected by soldering to electrodes at the solar battery cells c at one side, and the conductor exposed parts 4e that are not connected to the respective branch portions of the trunk portion 32, 42, or 62 are soldered to connecting portions installed in the solar battery cells c at another side (The connecting lead wire 61 of FIG. 6 does not comprise the conductor exposed part 4e that is not connected to the branch portions 63a, 63b of the trunk portion 62).

Further, the enamel wire (first branch portion 33a, 43a, or 63a) protruded in a lateral direction from the trunk portion 32, 42, or 62 outputs an electric current supplied from the whole module main body 110b to the outside, by being connected to an external output lead wire of the module main body 110b. As described above, the connecting lead wires 31, 41, and 61 are installed in the module main body 110b respectively, to provide the solar battery module 110 respectively.

In the configuration of each of the connecting lead wire 31, 41, and 61, the trunk portions 32, 42, and 62 each comprising the enamel wire are connected by soldering to the first branch portions 33a, 43a, and 63a each comprising the enamel wire similarly to the trunk portion, respectively. Therefore, the enamel wire originally comprising the solder plating layer 6 is used.

Further, the connecting lead wire 31 of FIG. 3 shows an example of the connecting lead wire 1 of FIG. 1. As clearly understood from FIG. 3, a fillet f comprising a solder plating is formed at a periphery of each bonding parts between the trunk portion 32 and the branch portions 33a, 33b, so that a good bonding condition is provided.

### Example 3

### Corresponding to the Connecting Lead Wire 51 of FIG. 5

At first, a Cu-wire (center conductor) 4 having a conductor diameter of φ1.5 mm is prepared. Then, a high melting point solder comprising Sn and inevitable impurities is provided on the Cu-wire 4 by electrolysis electroplating method until a thickness of a solder plating layer 6 becomes 0.01 mm. Thereafter, a brazing polyurethane enamel coating material is applied to the high melting point solder plated Cu-wire 4 and annealed repeatedly until a thickness of a brazing polyurethane enamel coating layer 5 becomes 0.04 mm, so as to provide an enamel wire. The enamel coating layer 5 is removed in plural points at desired positions by mechanical method, and the enamel wire is cut with a length of 0.4 mm, to provide a segmented enamel wire (metal segmentation process).

One enamel wire to be used as a trunk portion 52 in which the enamel coating layer 5 is removed at desired positions to expose the conductor 4 at predetermined points (conductor exposed parts 4e) is selected. Another enamel wire (branch portion 53a) having the conductor exposed at both ends is soldered to the conductor exposed part 4e at one end of the enamel wire to be used as the trunk portion 52 (welding process) to provide a connecting lead wire 51 of FIG. 5.

The conductor exposed parts 4e of the trunk portion 52 are soldered to connecting portions installed in the solar battery cells c, so that the connecting lead wire 51 is installed in the module main body 110b to provide the solar battery module 110.

Further, the enamel wire (branch portion 53a) protruded in a lateral direction from the trunk portion 52 outputs an electric current supplied from the whole module main body 110b to the outside, by being connected to an external output lead wire of the module main body 110b.

In the configuration of the connecting lead wire 51, the trunk portions 52 comprising the enamel wire is connected by soldering to the branch portions 52a comprising the enamel wire similarly to the trunk portion. Therefore, the enamel wire originally comprising the solder plating layer 6 is used.

### Example 4

### Corresponding to the Connecting Lead Wire 71 of FIG. 7, which Uses the Ultrasonic Welding for Fabricating the Connecting Lead Wire 41 of FIG. 4

At first, a Cu-wire (center conductor) 4 having a conductor diameter of φ1.5 mm is prepared. Then, a brazing polyurethane enamel coating material is applied to the Cu-wire 4 and annealed repeatedly until a thickness of the brazing polyurethane enamel coating becomes 0.04 mm, so as to provide an enamel wire. An enamel coating layer 5 is removed in plural points at desired positions by mechanical method, and the enamel wire is cut with a length of 0.4 mm, to provide a segmented enamel wire (metal segmentation process). On the other hand, two rectangular wires each comprising a Cu-wire are prepared (second branch portion 73b).

In the enamel wire to be used as a trunk portion 72, the enamel coating layer 5 is removed to expose the conductor 4 at desired positions of a center part and an end (conductor exposed parts 4e). The rectangular wires (second branch portions 73b) are bonded by the ultrasonic welding to two conductor exposed parts 4e of the trunk portion 72 (ultrasonic welding process). Another enamel wire (first branch portion 73a) having the conductor exposed at both ends is bonded by the ultrasonic welding to the conductor exposed part 4e at one end of the trunk portion 72, to provide the connecting lead wire 71 of FIG. 7.

In the configuration of the connecting lead wire 71, the ultrasonic welding technique is used, so that it is not necessary to provide a solder plating layer in the rectangular wire (second branch portion 73b) and the enamel wires (trunk portion 72, first branch portion 73a), and the soldering process can be omitted.

By this ultorasonic welding, a crushing work is conducted on a welding end between the rectangular wire (second branch portion 73b) and the enamel wire (trunk portion 72, first branch portion 73a) by pressurizing in the ultrasonic welding, a surface of the trunk portion 72, a surface of the first branch portion 73a, and a surface of the second branch portion 73b are approximately in a condition of the same surface. Therefore, a thickness of the whole connecting lead wire 71 can be reduced.

Further, the second branch portions 73b are connected by soldering to electrodes of the solar battery cells c at one side. The trunk portion 72 has the conductor exposed parts 4e in which the enamel coating layer 5 is removed, at an end opposite to another end where the branch portions 73b are provided and at a region adjacent to a center part with respect to another end. In other words, the second branch portions 73b are not provided at the conductor exposed parts 4e at another end and the region adjacent to another end as shown in FIG. 7. These conductor exposed parts 4e are soldered to connecting portions installed in solar battery cells c at another side.

Further, the enamel wire (branch portion 73a) protruded in a lateral direction from the trunk portion 72 outputs an electric current supplied from the whole module main body 110b to the outside, by being connected to an external output lead wire of the module main body 110b. The connecting lead wire 71 thus fabricated is installed in the module main body 110b, to provide the solar battery module 110.

### Example 5

### Corresponding to the Connecting Lead Wire 81 of FIG. 8, which Uses the Ultrasonic Welding for Fabricating the Connecting Lead Wire 51 of FIG. 5

At first, a Cu-wire (center conductor) 4 having a conductor diameter of φ1.5 mm is prepared. Then, a brazing polyurethane enamel coating material is applied to the Cu-wire 4 and annealed repeatedly until a thickness of the brazing polyurethane enamel coating becomes 0.04 mm, so as to provide an enamel wire. An enamel coating layer 5 is removed in plural points at desired positions by mechanical method, and the enamel wire is cut with a length of 0.4 mm, to provide a segmented enamel wire (metal segmentation process).

One enamel wire to be used as a trunk portion 82 in which the enamel coating layer 5 is removed at desired positions to expose the conductor 4 at predetermined points (conductor exposed parts 4e) is selected. Another enamel wire (branch portion 83a) having the conductor exposed at both ends is soldered to the conductor exposed part 4e at one end of the enamel wire to be used as the trunk portion 82 (welding process) to provide a connecting lead wire 81 of FIG. 8.

The conductor exposed parts 4e of the trunk portion 82 are soldered to connecting portions installed in the solar battery cells c, so that the connecting lead wire 81 is installed in the module main body 110b to provide the solar battery module 110.

Further, the enamel wire (branch portion 83a) protruded in a lateral direction from the trunk portion 82 outputs an electric current supplied from the whole module main body 110b to the outside, by being connected to an external output lead wire of the module main body 110b.

### Example 6

### Corresponding to the Connecting Lead Wire 91 of FIG. 9, which Uses a Rectangular Wire

A rectangular Cu-wire (center conductor 4) having a thickness of 0.8 mm and a width of 2.2 mm is prepared. Then, a brazing polyurethane enamel coating material is applied to the rectangular Cu-wire 4 and annealed repeatedly until a thickness of the brazing polyurethane enamel coating becomes 0.04 mm, so as to provide an enamel wire. An enamel coating layer 5 is removed in plural points at desired positions by mechanical method, and the enamel wire is cut with a length of 0.4 m, to provide a segmented enamel wire (metal segmentation process).

On the other hand, two solder plated wires each having a rectangular lateral cross section are prepared (branch portion 93b). The solder plated wire is fabricated by providing a solder plating layer (Sn—Pb fusion solder plating containing P of 0.01 mass %) on a rectangular Cu-wire.

The enamel coating layer 5 of the enamel wire to be used as a trunk portion 92 is removed at desired positions of a center part and both ends to expose the conductor 4 at two points (conductor exposed parts 4e). Then, the solder plated wires each having a rectangular cross section (branch portions 93b) are soldered to the conductor exposed parts 4e (soldering process), to provide the connecting lead wire 91 of FIG. 9.

Thereafter, the branch portions 93b are connected by soldering to electrodes at solar battery cells c at one side. The trunk portion 92 has the conductor exposed parts 4e in which the enamel coating layer 5 is removed, at an end opposite to another end where the branch portions 93b are provided and at a region adjacent to the center part with respect to another end. In other words, the branch portions 93b are not provided at the conductor exposed parts 4e at another end and the region adjacent to another end as shown in FIG. 9. These conductor exposed parts 4e are soldered to connecting portions installed in solar battery cells c at another side, so that the connecting lead wire 91 is installed in a module main body 110b, so as to fabricate a solar battery module 110.

It is not necessary to specially form a solder plating layer at an enamel wire side in the solder bonding with the enamel wire to be used as the trunk portion 92, since the solder plated wire having a rectangular cross section originally comprises a solder plating layer. In other words, the solder plating layer is provided in the solder plated rectangular wire prior to the solder bonding.

### Example 7

### Corresponding to the Connecting Lead Wire 101 of FIG. 10, which Uses a Rectangular Wire

A rectangular Cu-wire (center conductor 4) having a thickness of 0.8 mm and a width of 2.2 mm is prepared. Then, a brazing polyurethane enamel coating material is applied to the rectangular Cu-wire 4 and annealed repeatedly until a thickness of the brazing polyurethane enamel coating becomes 0.04 mm, so as to provide an enamel wire. An enamel coating layer 5 is removed in plural points at desired positions by mechanical method, and the enamel wire is cut with a length of 0.4 m, to provide a segmented enamel wire (metal segmentation process). On the other hand, two solder plated wires each having a rectangular lateral cross section are prepared (second branch portion 103b).

A enamel wire to be used as a trunk portion 102 in which the enamel coating layer 5 is removed at desired positions to expose the conductor 4 at predetermined points (conductor exposed parts 4e) is selected. Another enamel wire (first branch portion 103a) having the conductor exposed at both ends is bonded by the ultrasonic welding to the conductor exposed part 4e at one end of the enamel wire to be used as the trunk portion 102 (welding process), and the rectangular wires each having a rectangular lateral cross section are bonded by the ultrasonic welding to other conductor exposed parts 4e at two positions to provide a connecting lead wire 101 of FIG. 10.

Further, the second branch portions 103b are connected by soldering to electrodes of the solar battery cells c at one side, and the conductor exposed parts 4e that are not connected to the respective branch portions of the trunk portion 102 are soldered to connecting portions installed in the solar battery cells c at another side.

Further, the enamel wire (first branch portion 103a) protruded in a lateral direction from the trunk portion 102 outputs an electric current supplied from the whole module main body 110b to the outside, by being connected to an external output lead wire of the module main body 110b. The connecting lead wire 101 thus fabricated is installed in the module main body 110b, to provide the solar battery module 110.

### Example 8

### Corresponding to the Connecting Lead Wire 151 of FIG. 11, which Uses a Rectangular Wire

A rectangular Cu-wire (center conductor 4) having a thickness of 0-8 mm and a width of 2.2 mm is prepared. A solder plating layer 6 (Sn—Pb fusion solder plating containing P of 0.01 mass %) is provided on the rectangular Cu-wire 4. Then, a brazing polyurethane enamel coating material is applied to the solder plating layer 6 formed on the rectangular Cu-wire 4 and annealed repeatedly until a thickness of the brazing polyurethane enamel coating becomes 0.04 mm, so as to provide an enamel wire. An enamel coating layer 5 is cut with a length of 0.4 in, to provide a first segmented enamel wire (metal segmentation process).

On the other hand, two solder plated wires each having a rectangular lateral cross section are prepared (second branch portions 153b). The solder plated wire is fabricated by providing a solder plating layer 6 (Sn—Pb fusion solder plating containing P of 0.01 mass %) on a rectangular Cu-wire 4. Further, a second enamel wire (branch portion 153a) is prepared. The second enamel wire is fabricated by providing a solder plating layer 6 (Sn—Pb fusion solder plating containing P of 0.01 mass %) on a Cu-wire 4 having a rectangular lateral cross section, and applying a brazing polyurethane enamel coating material to the solder plating layer 6 formed on the rectangular Cu-wire 4.

The solder plated wires each having a rectangular lateral cross section (second branch portions 153b) are soldered to the first enamel wire to be used as a trunk portion 152 at a center part and at a desired position at one end. The second enamel wire (first branch portion 153a) is soldered to the first enamel wire to be used as the trunk portion 152 at another end (soldering process), to provide a connecting lead wire 151 of FIG. 11.

Further, the second branch portions 153b are connected by soldering to electrodes of the solar battery cells c at one side, and a part of the trunk portion 152 that is not connected to the respective branch portions is soldered to connecting portions installed in the solar battery cells c at another side. Further, the second enamel wire (first branch portion 153a) protruded in a lateral direction from the trunk portion 152 outputs an electric current supplied from the whole module main body 110b to the outside, by being connected to an external output lead wire of the module main body 110b. The connecting lead wire 151 thus fabricated is installed in the module main body 110b, to provide the solar battery module 110.

In this connecting lead wire 151, the brazing enamel is provided on the trunk portion 152 and the first branch portion 153a, so that a direction solder bonding can be conducted. In the solder bonding between the trunk portion 152 and the first branch portion 153a, and the solder bonding between the trunk portion 152 and the second branch portions 153b, it is not necessary to remove the enamel coating layer 5 by mechanical method, and a lengthy enamel can be used for the solder bonding as fabricated.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A connecting lead wire for a solar battery module, in which a plurality of solar battery cells connected in series by an inter-connector are arranged, said connecting lead wire comprising:
a trunk portion comprising a conductor and an enamel coating layer provided on the conductor; and
a plurality of branch portions, each of the branch portions comprising a conductor and a solder plating layer provided on the conductor and protruding from the trunk portion in a lateral direction to be connected to an electrode of each of the solar battery cells, to connect the solar battery cells with each other.

2. The connecting lead wire for a solar battery module according to claim 1, wherein the trunk portion further comprises a solder plating layer between the conductor and the enamel coating layer.

3. A connecting lead wire for a solar battery module, in which a plurality of solar battery cells connected in series by an inter-connector are arranged, said connecting lead wire comprising:
a trunk portion comprising a conductor and an enamel coating layer provided on the conductor; and
a branch portion comprising a conductor and an enamel coating layer provided on the conductor and protruding from the trunk portion in a lateral direction, to take out an electric current from the solar battery cells.

4. The connecting lead wire for a solar battery module according to claim 3, wherein the trunk portion further comprises a solder plating layer between the conductor and the enamel coating layer, and the branch portion further comprises a solder plating layer between the conductor and the enamel coating layer.

5. The connecting lead wire for a solar battery module according to claim 1, wherein the trunk portion further comprises a conductor exposed part in which the enamel coating layer is removed.

6. The connecting lead wire for a solar battery module according to claim 1, wherein the solder plating layer comprises a Sn—Ag alloy, a Sn—Ag—Cu alloy, a Sn—Cu alloy, or a Sn—Pb alloy, which contains P of 0.002 to 0.02 mass %.

7. The connecting lead wire for a solar battery module according to claim 5, wherein a lateral cross section of the conductor is circular, elliptical, rectangular or polygonal.

8. A method for fabricating a connecting lead wire for a solar battery module, in which a plurality of solar battery cells connected in series by an inter-connector are arranged, the method for fabricating the connecting lead wire comprising the steps of:
preparing a trunk portion comprising a conductor and an enamel coating layer provided on the conductor;
partially removing the enamel coating layer of the trunk portion to expose a part of the conductor; and
soldering a branch portion comprising a conductor and a solder plating layer provided on the conductor to the exposed part of the conductor of the trunk portion.

9. The method for fabricating a connecting lead wire for a solar battery module, according to claim 8, wherein the trunk portion further comprises a solder plating layer between the conductor and the enamel coating layer.

10. The method for fabricating a connecting lead wire for a solar battery module, according to claim 9, wherein a part of the solder plating layer is provided on the exposed part of the conductor of the trunk portion.

11. The method for fabricating a connecting lead wire for a solar battery module, according to claim 9, further comprising the steps of partially removing an enamel coating layer provided on the solder plating layer of the branch portion to expose a part of the conductor, and soldering the exposed part of the conductor of the branch portion to the exposed part of the conductor of the trunk portion.

12. A method for fabricating a connecting lead wire for a solar battery module, in which a plurality of solar battery cells connected in series by an inter-connector are arranged, the method for fabricating the connecting lead wire comprising the steps of:
preparing a trunk portion comprising a conductor and an enamel coating layer provided on the conductor;
partially removing the enamel coating layer of the trunk portion to expose a part of the conductor; and
welding a branch portion comprising a conductor and a solder plating layer provided on the conductor to the exposed part of the conductor of the trunk portion.

13. The method for fabricating a connecting lead wire for a solar battery module, according to claim 12, wherein the trunk portion further comprises a solder plating layer between the conductor and the enamel coating layer.

14. The method for fabricating a connecting lead wire for a solar battery module, according to claim 12, wherein a part of the solder plating layer is provided on the exposed a part of the conductor of the trunk portion.

15. The method for fabricating a connecting lead wire for a solar battery module, according to claim 12, further comprising the steps of partially removing an enamel coating layer provided on the solder plating layer of the branch portion to expose a part of the conductor, and welding the exposed part of the conductor of the branch portion to the exposed part of the conductor of the trunk portion.

16. The method for fabricating a connecting lead wire for a solar battery module, according to claim 12, wherein a resistance welding method is used for the welding.

17. The method for fabricating a connecting lead wire for a solar battery module, according to claim 12, wherein a method combining a resistance welding, a laser welding or an ultrasonic welding is used for the welding.

18. The method for fabricating a connecting lead wire for a solar battery module according to claim 8, wherein the solder plating layer comprises a Sn—Ag alloy, a Sn—Ag—Cu alloy, a Sn—Cu alloy, or a Sn—Pb alloy, which contains P of 0.002 to 0.02 mass %.

19. A solar battery module comprising:
a plurality of solar battery cells connected in series by an inter-connector; and
a connecting lead wire for connecting the solar battery cells with each other, the connecting lead wire comprising:
a trunk portion comprising a conductor and an enamel coating layer provided on the conductor; and
a plurality of branch portions, each of the branch portions comprising a conductor and a solder plating layer provided on the conductor and protruding from the trunk portion in a lateral direction to be connected to an electrode of each of the solar battery cells.
